(19) United States
(12) Patent Application Publication
(10) Pub. No.: US 2006/0181340 A1
(43) Pub. Date: Aug. 17, 2006

(54) Regulating charge pump

(75) Inventor: Timothy Dhuyvetter, Arnold, CA (US)

Correspondence Address: LAW OFFICES OF CLEMENT CHENG, 17220 NEWHOPE STREET #127, FOUNTAIN VALLEY, CA, 92708, US

(73) Assignee: ZYWYN Corporation

(21) Appl. No.: 11/059,985

(22) Filed: Feb. 17, 2005

(51) Int. Cl. H03F 15/00

(52) U.S. Cl. 330/6

(57) ABSTRACT

A regulating charge pump includes a variable-configuration charge pump in combination with a linear regulator, the charge pump arranged within the linear regulator feedback loop to accurately control the charge pump output current or voltage. A charge pump of voltage gain N is utilized to advantageously reduce headroom required in a regulator circuit by substantially 1/N.

### FIELD OF THE INVENTION

This invention relates to electronic systems and more particularly to systems employing current and voltage regulators utilizing charge pumps.

### DISCUSSION OF RELATED ART

As the field of electronics and electronic components has advanced, and applications of battery operated and very compact low power electronic systems, such as cell phones, personal digital assistants, and portable computers, has advanced, it has become increasingly important to provide electronic circuitry capable of operation from a single battery, with very efficient circuitry to minimize load currents, provide good voltage regulation in order to adapt to the gradually decreasing voltage of the battery as it discharges; and to be capable of utilizing the battery until the maximum energy has been extracted in order to provide the longest possible battery life. When a load circuit voltage reaches a high value such that it begins to saturate the driving circuit, such as an amplifier, it is said to run out of headroom. The headroom is the margin of voltage available from a driver or amplifier that exceeds the voltage required by the load to maintain linear operation of the driver or amplifier. Circuitry requiring low headroom is advantageous since it requires lower source voltage and potentially fewer cells in a battery power source.

Relatively recent innovations, now commonly known by those experienced in the field, lend themselves to these requirements. Charge pumps use electronic switches (such as MOS-FETS) to rapidly switch energy-storage capacitors back and forth from series connections to parallel connections with voltage sources in order to increase voltage source potential. This is accomplished by transferring energy to a load during the time that the capacitor is connected in series with the voltage source. New energy is captured from the voltage source by the capacitor during the time that it is connected in parallel with the voltage source.

Thus charge pumps require clock circuits to operate their electronic switches, but such clock circuits can be easily incorporated into the same chip design along with the charge pump. Thus a very efficient, integrated, low cost method is available for approximately doubling a supply voltage. By extending the concept with additional switches and capacitors, supply voltages can be created that are 1.5 times the supply voltage, and other multiples. A general and well-known limitation of charge pumps is the poor voltage regulation due to the sensitivity of output voltage with respect to loading current. What is desirable is a method to utilize the several advantages of charge pumps while providing accurate and stable output voltages or currents as the loads change, whether due to impedance changes with frequency, to variations with temperature, or simply changes in impedance for variable current demand applications.

Another development in modern circuit design is the Low Drop Out (LDO) regulator. This is generally a voltage or current regulator with internal circuitry that is able to operate over a wide supply voltage range, including very low supply voltages in order to operate battery powered devices down to very low battery voltage levels.

### SUMMARY OF THE INVENTION

The present invention incorporates both charge pumps and regulator amplifiers, such as LDO regulators, in a novel feedback configuration that stabilizes the output voltage or current of a charge pump by placing the charge pump inside the feedback loop of the regulator. Because the charge pump is within the a feedback loop, precision regulation is made possible by closing the feedback loop, for a wide range of charge pump characteristics, load currents, temperature ranges, and signal frequency for uses involving voltage or current regulation varying in time. Furthermore, the present invention allows the use of low-voltage batteries, with fewer cells, to provide precision control for circuits requiring higher voltages, thereby reducing battery cost in electronic systems. In a Regulating Charge Pump utilizing a charge pump of voltage gain N, headroom required by the regulating amplifier is substantially reduced by a factor 1/N. Typical charge pumps useable in the present invention are 1.5×, 2×, 3×, etc. wherein the voltage multiplication of the charge pump is 1.5, 2, 3, etc.

Other features and advantages of the present invention will become apparent from the following more detailed description, taken in conjunction with the accompanying drawings, which illustrate, by way of example, the principles of the invention.

### DESCRIPTION OF THE DRAWINGS

FIG. 1 is an electrical schematic diagram of the present invention in the first preferred configuration as a voltage-regulating charge pump;

FIG. 2 is a simplified electrical diagram of a prior-art charge pump for generating approximately two times the supply voltage;

FIG. 3 is a simplified electrical diagram of a prior-art charge pump for generating approximately one and one-half times the supply voltage;

FIG. 4 is an electrical schematic diagram of the present invention in the second preferred configuration as a current-regulating charge pump; and

FIG. 5 illustrates an application of the current-regulating charge pump of FIG. 4 driving an array of Light Emitting Diodes (LEDs).

### DETAILED DESCRIPTION OF THE PREFERRED EMBODIMENT

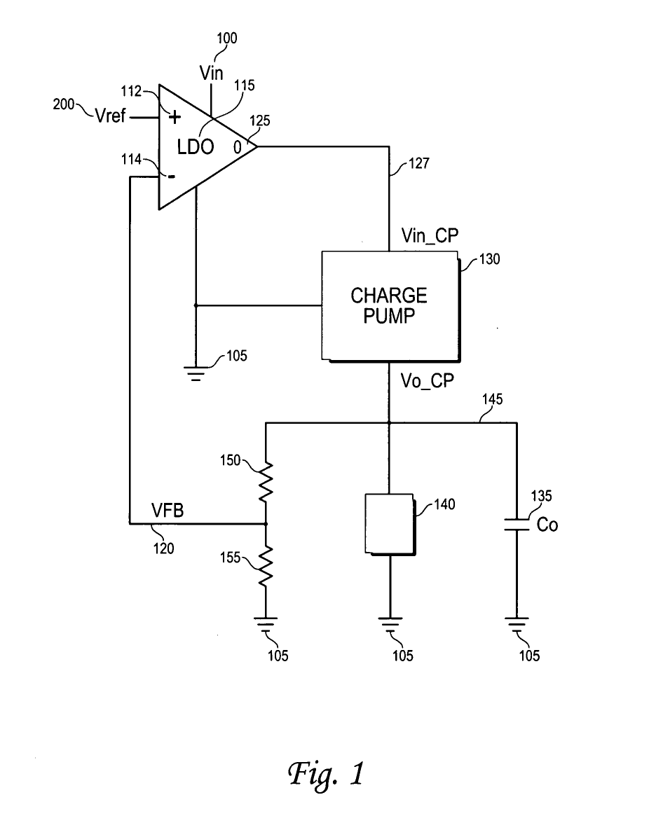

Referring to FIG. 1, a regulated output voltage source useable in a variety of circuits is generated at output Vo-cp 145. Voltage energy source Vᵢₙ 100 and ground 105 from power supply or battery, not shown, supply LDO 115 with power. V_{ref} 110 is the input voltage reference for the circuit and is connected to LDO non-inverting input 112, and represents the desired voltage to which the Regulating Charge Pump (RCP) of the invention is to regulate its output, Vo-cp 145. LDO regulators are common in the field of electronics and may be manufactured using common silicon fabrication techniques and employing bipolar and/or Metal Oxide Semiconductor (MOS) and/or Complimentary Metal Oxide Semiconductor (CMOS) or other common integrated circuit technologies and are well known in the art. The output of LDO 115 at connection 125 is coupled to the input terminal V_{in-cp} 127 of charge pump 130, which also has a connection to ground 105 and utilizes clock circuitry not shown. Clock circuits and charge pump circuits may be manufactured using common silicon fabrication techniques and employing MOS and/or CMOS or other integrated circuit technologies and are well known in the art. An output capacitor Co 135 and load 140 are connected to charge pump output V_{o-cp} 145 as well as to resistor 150. Resistor 150 is coupled to resistor 155, which is connected to ground 105, forming a feedback network to create a feedback signal V_{cb} 120 which is in turn connected to the LDO inverting input 114.

Normally and in typical use, charge pump 130 would have a fixed supply voltage at it's voltage energy source V_{in-cp} 127 terminal and it's output Vo-cp 145 would fluctuate in response to variations in load current. However, in the present invention RCP circuit of FIG. 1, LDO 115, which acts as a high-gain, low output impedance amplifier, responds to variations in output voltage Vo-cp 145 through feedback signal V_{fb} 120 to quickly change LDO output 125 and thereby change charge pump 130 input V_{in-cp} 127 to correct the error sensed in its output V_{o-cp} 145. In this way the charge pump output voltage Vo-cp 145 is tightly regulated with respect to load fluctuations, temperature, and input voltage reference V_{ref} 110 temporal variations within the bandwidth response capabilities of the selected LDO and the selected charge pump.

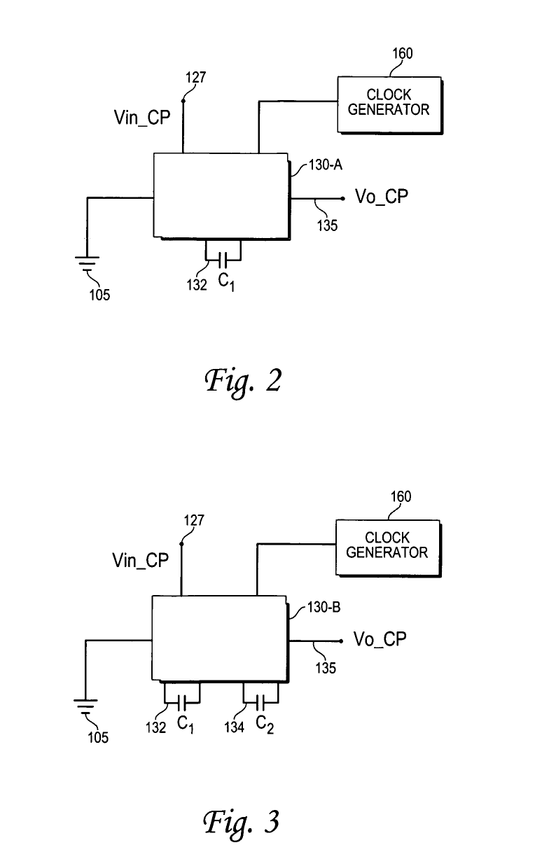

FIG. 2 represents a voltage-doubling charge pump 130-A useable in RCP circuits. Clock generator 160 supplies the switching clocks for the internal electronic switches (not shown) of charge pump 130-A. The source for power for the device is connected to the voltage energy source V_{in-cp} 127 terminal, such as a battery or power supply (not shown), and also connects to the ground 105 terminal of the charge pump. Capacitor C1 132 is the energy-transferring component commonly termed a “fly cap”. The output Vo-cp 135 connects to an output capacitor, not shown, to filter the output voltage from switching transients. The internal circuitry of charge pump 130-A may take on any of a number of configurations in the art since the RCP circuit of the present invention is tolerant of variations in the configuration of charge pumps since the charge pump is placed inside a feedback loop.

FIG. 3 represents a charge pump 130-B of voltage gain of approximately 1.5 useable in RCP circuits. Clock generator 160 supplies the switching clocks for the internal electronic switches (not shown) of charge pump 130-B. Input voltage energy source V_{in-cp} 127 is the source for power for the device, such as a battery or power supply (not shown), and connects to the ground 105 terminal of the charge pump. Capacitors C1 132 and C2 134 are the energy-transferring “fly cap” components. The output Vo-cp 135 connects to an output capacitor, not shown, to filter the output voltage from switching transients.

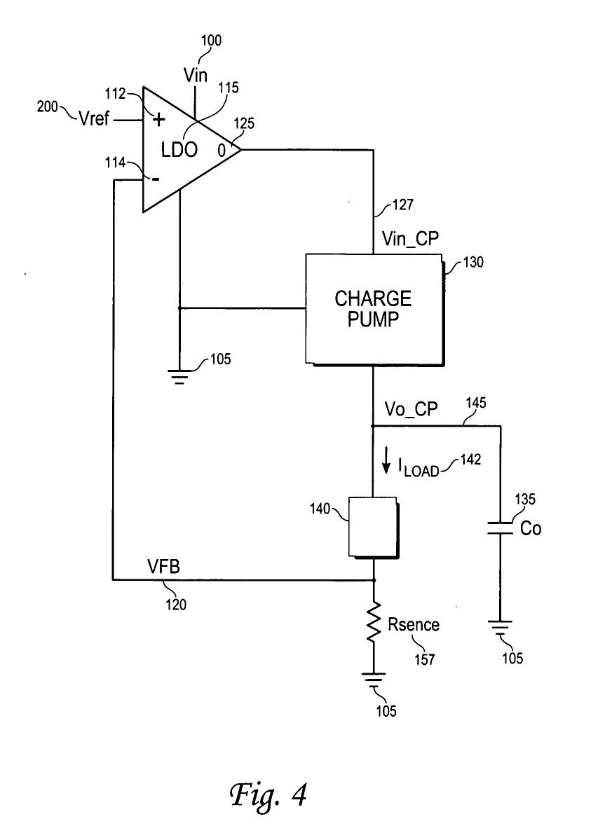

FIG. 4 is an RCP circuit termed a current-regulating charge pump and illustrates a second preferred embodiment of the present invention. A regulated output current source I_{load} 142 useable in a variety of circuits is caused to flow along lead 225. Voltage energy source Vᵢₙ 100 and ground 105 from power supply or battery, not shown, supply LDO 115 with power. V_{ref} 110 is the input voltage reference for the circuit and is connected to the LDO non-inverting input 112, and represents, through the relationship:
I_{load}=V_{ref}/Rₛₑₙₛₑ
the desired current to which the RCP of the invention is to regulate its output current I_{load} 142. The output of LDO 115 at connection 125 is coupled to the input terminal V_{in-cp} 127 of charge pump 130, which also has a connection to ground 105 and utilizes clock circuitry not shown. An output capacitor Co 135 from ground 105 and load 140 are connected to charge pump output V_{o-cp} 145. Current sense resistor Rₛₑₙₛₑ 157 is coupled between load 140 and ground 105. Resistor 157 and load current I_{load} flowing therethrogh creates a feedback signal V_{fb} 120 that is in turn connected to the LDO inverting input 114.

In the second preferred embodiment RCP circuit of FIG. 4, LDO 115, which acts as a high-gain, low output impedance amplifier, responds to slight variations in I_{load} 142 through feedback signal V_{fb} 120 developed by load current I_{load} 142 flowing through feedback network resistor Rₛₑₙₛₑ 157 to quickly change LDO output 125 and thereby change charge pump 130 input V_{in-cp} 127 to correct the error sensed. In this way the RCP load current I_{load} 142 is tightly regulated with respect to load impedance fluctuations, temperature, and input voltage reference V_{ref} 110 temporal variations within the bandwidth response capabilities of the selected LDO and the selected charge pump.

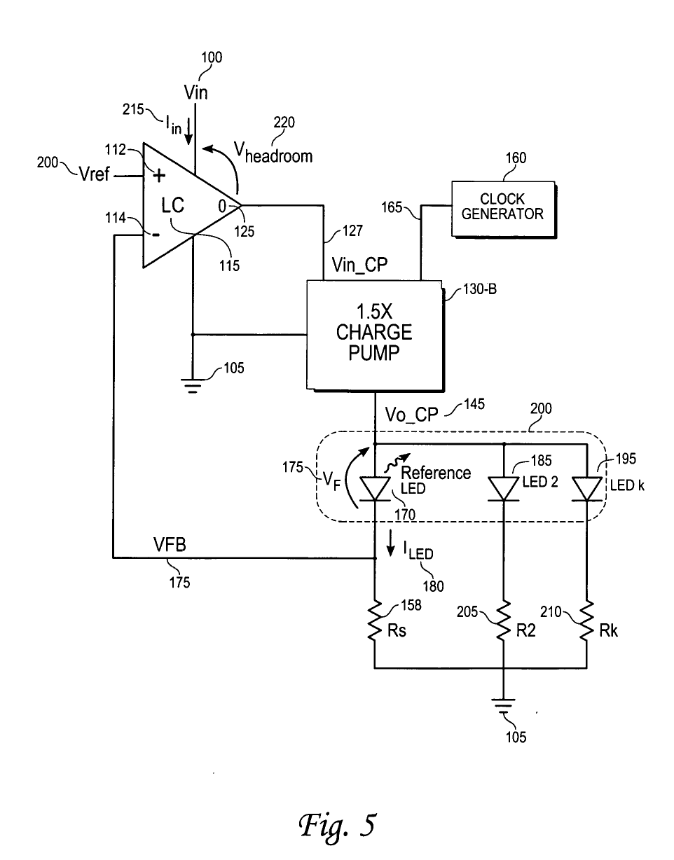

FIG. 5 is an electrical schematic diagram of an RCP of the second preferred embodiment utilized in an application for controlling the intensity of the output light from an LED Array 200 by controlling I_{LED} 180 through the single reference LED 170. LED Array 200 includes k LEDs diagrammed as reference LED 170, LED2 185 through LEDk 195. In these applications, such as battery-powered devices with back-illuminated displays, it is important to not only extend battery life as much as possible, but also to insure that each LED in an array provides similar output light intensity as the other LEDs in the array. Prior art systems have controlled LED variations by controlling the voltage across such LEDs with a voltage determined by one LED (need document reference), the reference LED forward voltage V_{f} 175. FIG. 5 incorporates this feature with an RCP in order to more accurately control all LED intensities over large battery voltage variations, and responsive to desired variations of the intensity through variation of input voltage reference V_{ref} 110. Resistors R₂ 205 and Rₖ 210 may be of value equal to sense resistor Rₛ 158 such as 51 ohms (need value used). Furthermore, this precision intensity control can be achieved with a low voltage battery (need value and maybe a vendor component number) in spite of the higher voltage requirements of LEDs, such as white LEDs requiring approximately 3.4 volts (need value seen with parts used) forward voltage.

In FIG. 5 voltage energy source Vᵢₙ 100 and ground 105 from power supply or battery, not shown, supply LDO 115 with power. V_{ref} 110 is the input voltage reference for the circuit and is connected to the LDO (need value and maybe a vendor component number) non-inverting input 112 to control the current through LED 170 to I_{LED} 180 monitored on sense resistor Rₛ 158, and represents, through the relationship:
LED=V_{ref}/Rₛ
the desired current to which the RCP of the invention is to regulate LED current I_{LED} 180. The output of LDO 115 at connection 125 is coupled to the input terminal V_{in-cp} 127 of 1.5× charge pump 130-B (need value and maybe a vendor component number), which also has a connection to ground 105 and utilizes clock generator 160 the design of which is well known in the art (need value and maybe a vendor component number) coupled to charge pump 130 by connection 165. An output capacitor Co 135 from ground 105 (need value and maybe a vendor component number) is connected to charge pump output V_{o-cp} 145 and to ground 105. Resistor Rₛ 158 and load current I_{LED} 180 flowing therethrogh creates a feedback signal V_{fb} 120 that is in turn connected to the LDO inverting input 114.

In the application of FIG. 5, LDO 115, which acts as a high-gain, low output impedance amplifier, responds to slight variations in I_{LED} 180 through feedback signal V_{fb} 120 to quickly change LDO output 125 and thereby change charge pump 130-B input V_{in-cp} 127 to correct the error sensed in LED current I_{LED} 180. In this way the LED current I_{LED} 180 is tightly regulated with respect to supply voltage Vᵢₙ 100, temperature, and input voltage reference V_{ref} 110 variations. Headroom voltage margin V_{headroom} 220 is the voltage difference between Vᵢₙ 100 and V_{in-cp} 127. The current drawn by the circuit is total current Iᵢₙ 215. Utilizing the variable names provided above, the headroom required of LDO 115 and power source Vᵢₙ 100 is derived below (dc analysis):
V_{o-cp}=V_{f}+V_{fb}=V_{f}+Rₛ×I_{LED}

V_{o-cp}=N×V_{in-cp}, where N=voltage multiplication of charge pump
so that
V_{in-cp}=V_{o-cp}/N
Vᵢₙ=V_{in-cp}+V_{headroom}
therefore,
V_{headroom}=Vᵢₙ−V_{o-cp}/N
Finally,
V_{headroom}=Vᵢₙ−(1/N)×(V_{f}+Rₛ×I_{LED})

The second term in the above equation illustrates that the headroom voltage margin is reduced by the factor of (1/N) through the use of a charge pump within a current regulator feedback loop.

By making the assumption that each LED in LED array 200 draws a current substantially equal to reference LED 170, and that a quiescent current I_{Q}, not shown, is drawn by LDO 115, charge pump 130-B, and clock circuits 160, then the total current is:
Iᵢₙ=N×I_{LED}+I_{Q}

Although preferred regulating circuitry has been described, other electronic circuits may advantageously be connected as voltage multiplying circuits within amplifier feedback loops that are also within the scope of this invention. Thus, while the invention has been described herein with reference to certain preferred embodiments, these embodiments have been presented by way of example only, and not to limit the scope of the invention. Accordingly, other embodiments and changes in form and detail may be made therein by one skilled in the art without departing from the spirit and scope of the invention, including embodiments which do not provide all of the benefits and features set forth herein.

1. A regulating charge pump for providing a regulated output voltage source comprising:
an input voltage energy source;
an input voltage reference;
regulator amplifier means;
charge pump means; and
clock generator means, said charge pump means connected within a feedback loop of said regulator amplifier means to control said regulated output voltage source.

2. The regulating charge pump of claim 1 wherein said regulator amplifier means is an LDO regulator.

3. The regulating charge pump of claim 1 wherein said charge pump means is a 1.5× charge pump.

4. The regulating charge pump of claim 1 wherein said charge pump means is a 2× charge pump.

5. A regulating charge pump for providing a regulated output current source comprising:
an input voltage energy source;
an input voltage reference;
regulator amplifier means;
charge pump means; and
clock generator means, said charge pump means connected within a feedback loop of said regulator amplifier means to control said regulated output current source.

6. The regulating charge pump of claim 5 wherein said regulator amplifier means is an LDO regulator.

7. The regulating charge pump of claim 5 wherein said charge pump means is a 1.5× charge pump.

8. The regulating charge pump of claim 5 wherein said charge pump means is a 2× charge pump.

9. A method for generating a regulated output voltage source including:
coupling a voltage energy source to a regulator amplifier;
coupling an input voltage reference to the non-inverting input of said regulator amplifier;
coupling the output of said regulator amplifier to the input energy source terminal of a charge pump;
coupling the output terminal of said charge pump to a feedback network; and
coupling said feedback network to the inverting input of said regulator amplifier to close the feedback loop and regulate said regulated output voltage source.

10. A method for generating a regulated output current source including:
coupling a voltage energy source to a regulator amplifier;
coupling an input voltage reference to the non-inverting input of said regulator amplifier;
coupling the output of said regulator amplifier to the input energy source terminal of a charge pump;
coupling the output terminal of said charge pump to a feedback network; and
coupling said feedback network to the inverting input of said regulator amplifier to close the feedback loop and regulate said regulated output current source.
